(19) United States
(12) Patent Application Publication
(10) Pub. No.: US 2012/0181053 A1
(43) Pub. Date: Jul. 19, 2012

(54) ELECTRONIC DEVICE HAVING LIMITING MECHANISM

(75) Inventors: TING-TING ZHAO, Shenzhen City (CN); NA WANG, Shenzhen City (CN); HE-LI WANG, Shenzhen City (CN); WEI LIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/173,169

(22) Filed: Jun. 30, 2011

(30) Foreign Application Priority Data
Jan. 18, 2011 (CN) 201110020343.0

(51) Int. Cl. H05K 5/00

(52) U.S. Cl. 174/50

(57) ABSTRACT

An electronic device includes a body, a cover rotatably mounted to the body, and at least one limiting mechanism rotatably mounted to the body. The at least one limiting mechanism includes a connecting member mounted to the cover and a limiting member arranged on the connecting member. The limiting member resists against the body to limit the movement of the cover in a direction parallel to the axis.

### BACKGROUND

1. Technical Field

The present disclosure relates to electronic devices; and particularly to an electronic device with a cover rotatably mounted thereon.

2. Description of Related Art

Electronic devices, such as a DVD player, may include a body, a display rotatably covering the body, and a cover rotatably mounted on the body. The cover acts as an entrance for allowing discs to be loaded and unloaded when the cover is open. The cover is typically coupled to the body via a pivoting shaft, and is rotatable around an axis (for example, the pivoting shaft) relative to the body. However, the cover always moves back and forth in a direction parallel to the axis when being opened and this may cause the cover to not being closed correctly.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout five views.

FIG. 1 is a perspective view of an electronic device in accordance with an exemplary embodiment; the electronic device includes a body and a cover having a limiting member.

FIG. 2 is a perspective view showing the cover of the electronic device of FIG. 1 being open.

FIG. 3 is a partially disassembled perspective view of the electronic device of FIG. 1.

FIG. 4 is an enlarged view of IV portion of FIG. 3.

FIG. 5 is a perspective view showing the limiting member of the cover resisting against the body.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

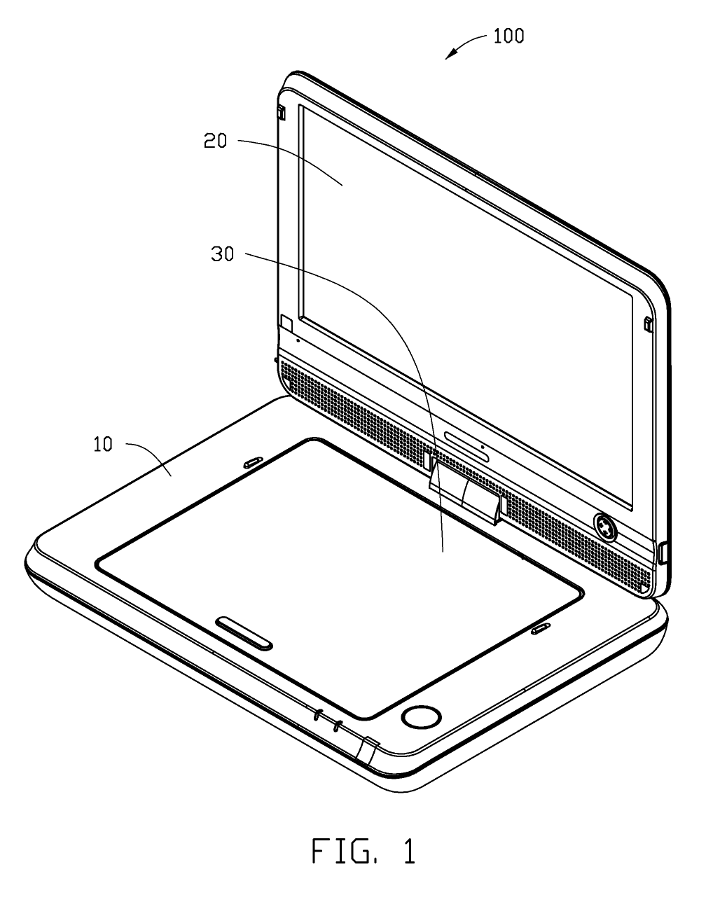

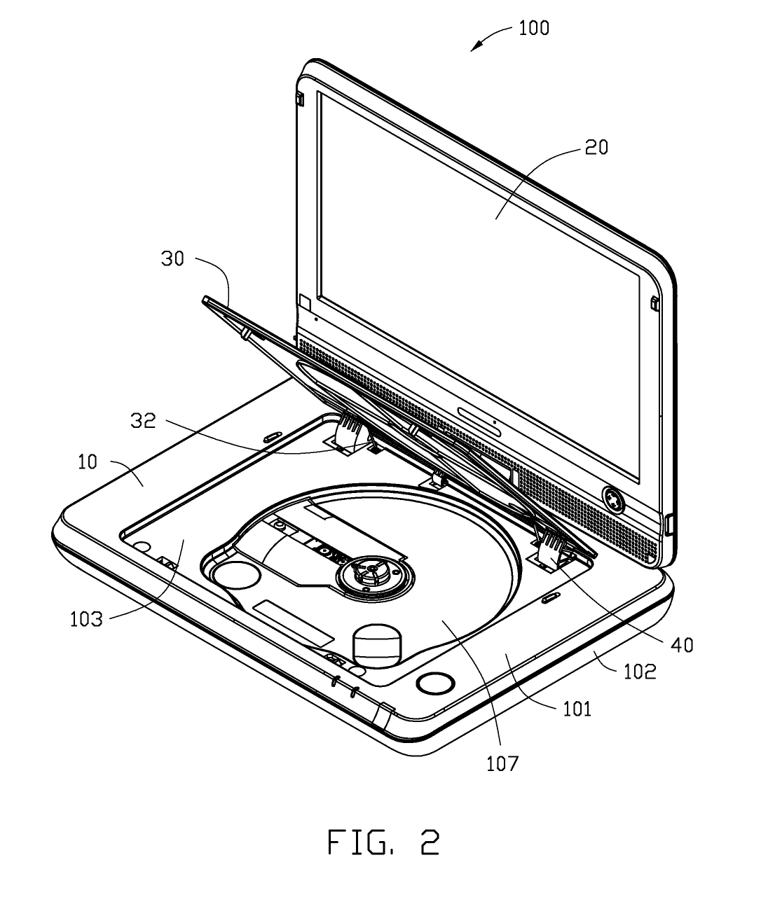

Referring to FIGS. 1 and 2, a perspective view of an electronic device 100 in accordance with an embodiment is shown. The electronic device 100 includes a body 10, a display 20 rotatably mounted to a rear side of the body 10, and a cover 30 rotatably mounted to a top surface of the body 10. In the embodiment, the electronic device 100 may be a portable disc player.

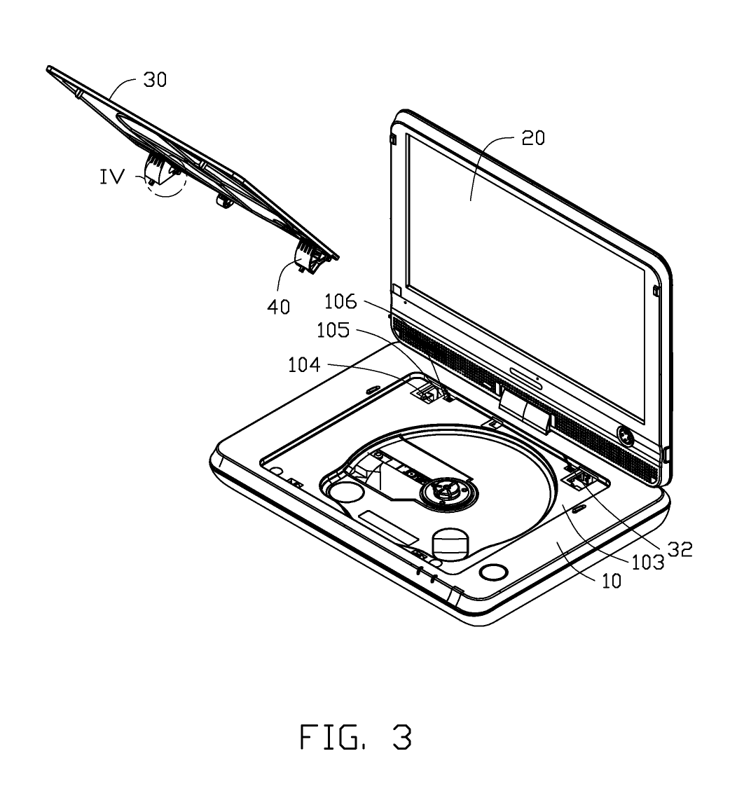

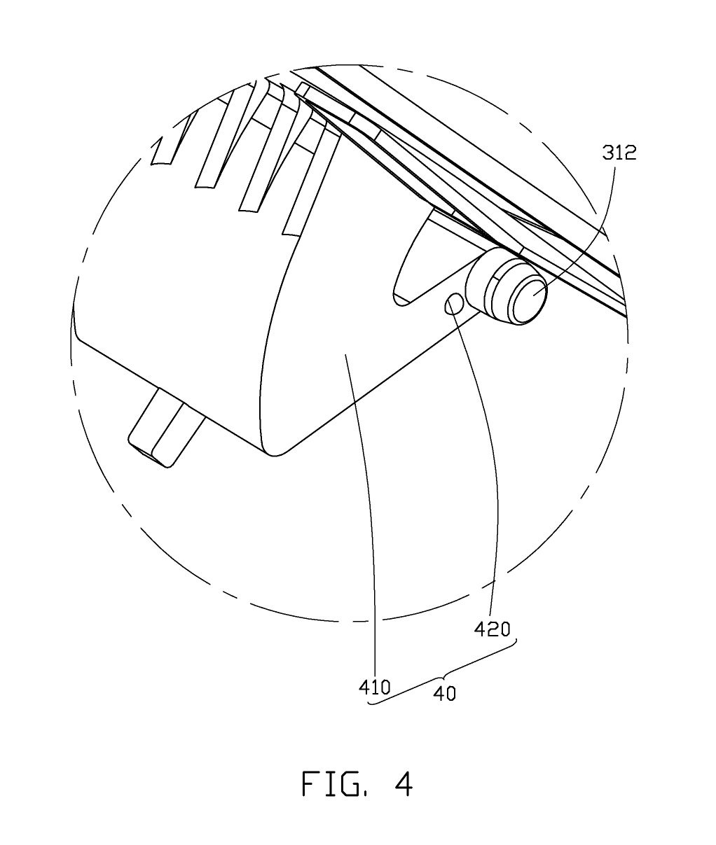

Referring also to FIGS. 3 and 4, the body 10 is used to accommodate components, such as motherboard, processor, disc drive, and other components (not shown) for operating the electronic device 100 therein. The body 10 includes a top case 101 and a bottom case 102 engaging with the top case 101. The top case 101 and the bottom case 102 cooperatively define a receiving space (not shown) for accommodating a motherboard, a processor, a disc drive, and other components. A receiving portion 103 configured for receiving the cover 30 is defined on the top surface of the top case 101. A recess 107 is defined on the bottom surface of the receiving portion 103 and configured for accommodating a disk (not shown). The cover 30 is configured for covering the disk. Two corners of the receiving portion 103 respectively define two openings 104 communicating between the receiving space and the receiving portion 103. The top case 101 further defines two axial holes 105 respectively communicating with the two openings 104. The bottom of the receiving portion 103 further defines two receiving grooves 106 located between the openings 104. The receiving grooves 106 are respectively adjacent to the openings 104.

The cover 30 is substantially rectangular and includes two pivoting rods 312 disposed on two opposite sides of the cover 30. The cover 30 is rotatably coupled to the body 10 via the two pivoting rods 312. The pivoting rods 312 have an axis parallel to a rear side of the cover 30.

The electronic device 100 further includes two limiting mechanisms 40 disposed on the cover 30 and respectively adjacent to the two pivoting rods 312. Each limiting mechanisms 40 includes a connecting member 410 and a limiting member 420 arranged on the connecting member 410. The connecting members 410 are arranged on a rim of the cover 30 and are corresponding to the openings 104. In the embodiment, the connecting members 410 protrude from a surface of the cover 30 facing the receiving portion 103, and the pivoting rods 312 protrude from the connecting member 410. The width W of the connecting member 410 is less than the width S of the corresponding opening 104, such that the connecting member 410 can be received in the corresponding opening 104. The limiting member 420 protrudes from the connecting member 410 and is adjacent to the pivot rod 312. In the embodiment, the limiting member 420 integrally protrudes from the connecting member 410 and extends in a direction parallel to the axis. The sum of the length L of the limiting member 420 protruding out of the corresponding connecting member 410 and the width W of the connecting member 410 is substantially equal to the width S of the opening 104.

The electronic device 100 further includes two elastic elements 32. The elastic elements 32 are V-shaped torsion springs in the embodiment. The two elastic elements 32 are received in the receiving grooves 106 respectively. Opposite ends of the elastic elements 32 are mounted to the cover 30 and the body 10 respectively, to provide an elastic force between the cover 30 and the body 10 when the cover 30 covers the body 10.

In assembly, the pivoting rods 312 are rotatably received in the corresponding pivot holes 105, and the connecting members 410 are received in the corresponding openings 104 with the limiting members 420 resisting against a sidewall of the opening 104. The elastic elements 32 are received in the corresponding receiving groove 106 with opposite ends mounted to the body 10 and the cover 20.

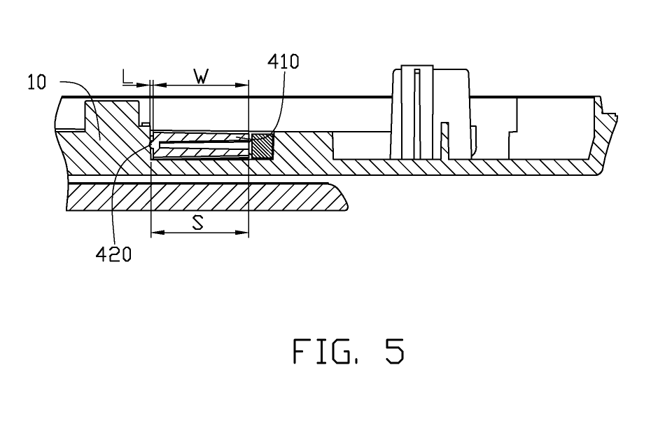

Referring to FIG. 5, as the sum of the length L of the limiting member 420 protruding out of the corresponding connecting member 410 and the width W of the connecting member 410 is substantially equal to the width S of the opening 104. The limiting members 420 protrude from the connecting members 410 and resist against the sidewall of the opening 104. The clearance between the sidewall of the openings 104 and the connecting members 410 allowing the connecting members 410 to move in the direction parallel to the axis is reduced or eliminated. As a result, the movement of the cover 30 in a direction parallel to the axis can be limited.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a body;
a cover rotatably mounted to the body, wherein the cover is rotatable relative to the body around an axis; and
at least one limiting mechanism, the at least one limiting mechanism comprising a connecting member mounted to the cover and a limiting member arranged on the connecting member, the limiting member resisting against the body to limit the movement of the cover in a direction parallel to the axis.

2. The electronic device of claim 1, wherein the limiting member integrally protrudes from the connecting member.

3. The electronic device of claim 2, wherein the limiting member extend in a direction parallel to the axis.

4. The electronic device of claim 1, wherein the connecting member is arranged on a rim of the cover and is rotatably received in the body.

5. The electronic device of claim 1, wherein the body defines a receiving portion for receiving the cover.

6. The electronic device of claim 1, wherein the bottom surface of the receiving portion further defines a recess.

7. The electronic device of claim 6, wherein the electronic device is a disc player for receiving a disc in the recess, and the cover covers on the disc.

8. The electronic device of claim 5, wherein two corners of the bottom surface of the receiving portion respectively define an opening for receiving the connecting member, the limiting member resists against a sidewall of the opening.

9. The electronic device of claim 8, wherein the sum of the length of the limiting member protruding out of the connecting member and the width of the connecting member is substantially equal to the width of the opening.

10. The electronic device of claim 9, further comprising at least one pivoting rod, the at least one pivoting rod arranged on the connecting member and extending in a direction parallel to the axis.

11. The electronic device of claim 10, wherein the body defines an axial hole receiving the at least one pivoting rod and communicating with the open.
